(19) United States
(12) Patent Application Publication
(10) Pub. No.: US 2016/0150666 A1
(43) Pub. Date: May 26, 2016

(54) CHASSIS

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: HE-TAO HAN, wuhan (CN); CHUN-YONG XU, Wuhan (CN); YUAN-GANG SHU, Wuhan (CN); JUN-HUA TAN, wuhan (CN); XIAO-ZHONG JING, Wuhan (CN); YI-SHENG LIN, New Taipei (TW); LIANG-CHIN WANG, New Taipei (TW)

(21) Appl. No.: 14/587,278

(22) Filed: Dec. 31, 2014

(30) Foreign Application Priority Data
Nov. 24, 2014 (CN) 201410678721.8

(51) Int. Cl. H05K 7/14; G06F 1/18

(52) U.S. Cl. CPC H05K 7/1489; G06F 1/183

(57) ABSTRACT

A chassis includes a shell, two sliding rails, a slider and a bracket. The two sliding rails are fixed to the shell. The slider is slidably fixed to one of the two sliding rails. The slider includes a positioning post. The bracket defines a groove. The positioning post is located in the groove and moves from a first position to a second position along the groove. When the positioning post is located at the first position, the bracket is locked with the shell. When the positioning post is located at the second position, the bracket is unlocked from the shell and can move away relative to the shell.

### CROSS-REFERENCE TO RELATED APPLICATIONS

This application claims priority to Chinese Patent Application No. 201410678721.8 filed on Nov. 24, 2014, the contents of which are incorporated by reference herein.

### FIELD

The subject matter herein generally relates to chassis.

### BACKGROUND

Electronic devices, such as microprocessor based computer systems, typically include motherboards and a plurality of storage devices. When the motherboards and the plurality of storage devices are damaged or need repair, the chassis needs to be disassembled.

### BRIEF DESCRIPTION OF THE DRAWINGS

Implementations of the present technology will now be described, by way of example only, with reference to the attached figures.

FIG. 1 is an exploded, isometric view of one embodiment of a chassis.

FIG. 2 is similar to FIG. 1, but viewed from another angle.

FIG. 3 is an assembled, isometric view of the chassis of FIG. 1 where the positioning post is located at a first position.

FIG. 4 is similar to FIG. 3, but the positioning post is located at a second position.

FIG. 5 is similar to FIG. 4, but the chassis is disassembled.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a chassis.

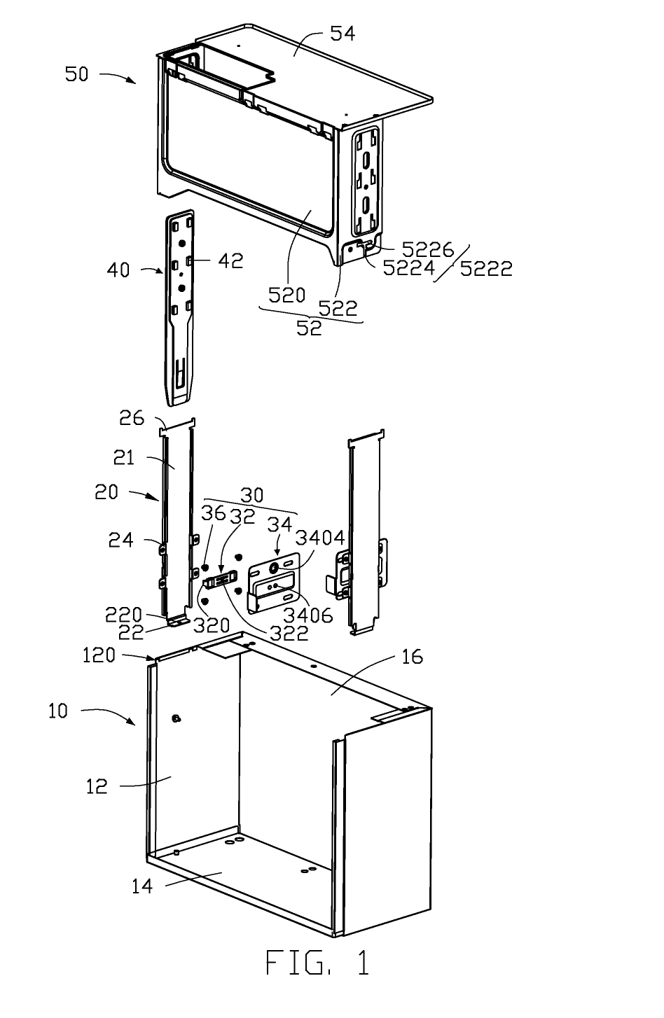

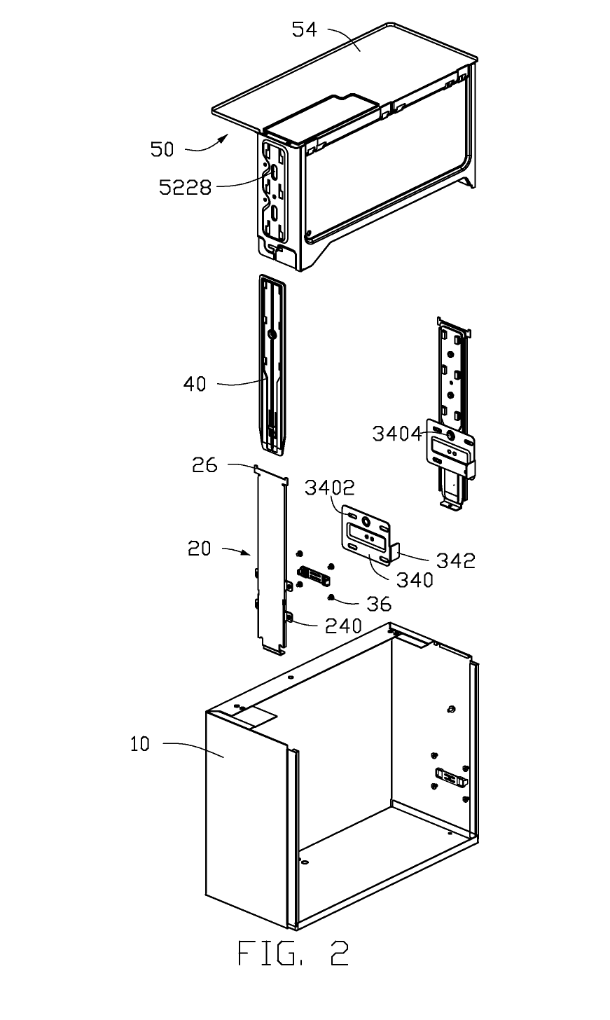

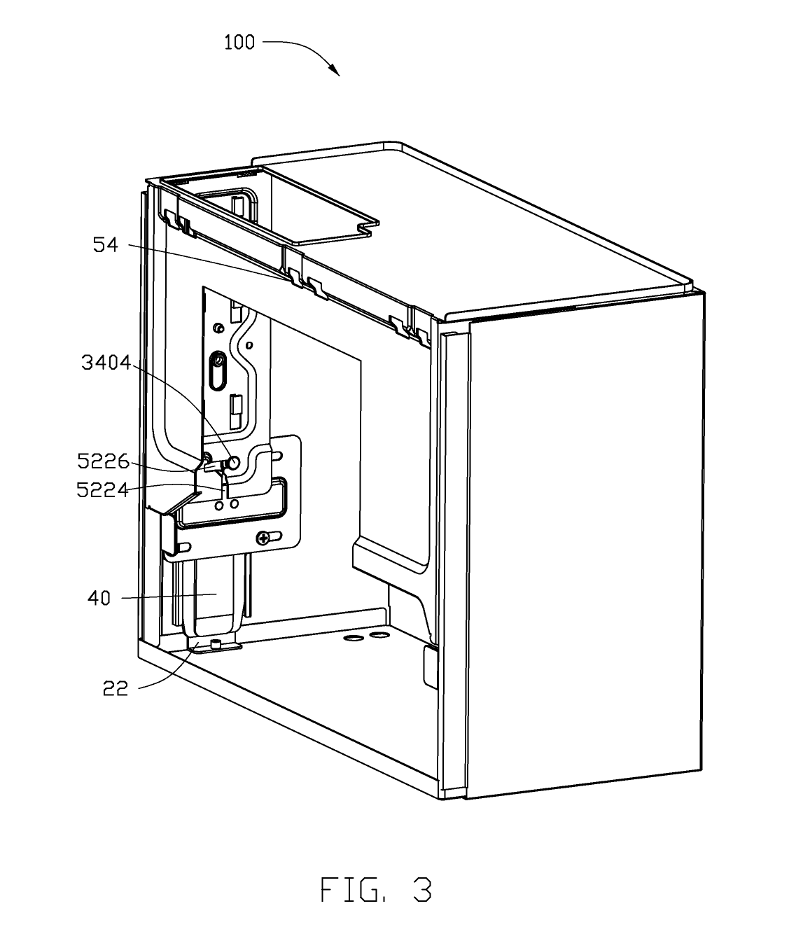

FIGS. 1 and 2 illustrate one embodiment of a chassis 100. (as shown in FIG. 3) The chassis 100 includes a shell 10, two sliding rails 20, two sliders 30, two sliding bars 40, and a bracket 50.

The shell 10 includes two side plates 12, a front plate 14, and a bottom plate 16. The two side plates 12 and the front plate 14 can be substantially perpendicular to the bottom plate 16. The two side plates 12 can be substantially perpendicular to the front plate 14. The two side plates 12 are substantially parallel to each other. Each side plate 12 defines two locking portions 120.

Each sliding rail 20 includes a main portion 21, a fixing portion 22, four fixing pieces 24, and two locking pieces 26. The fixing portion 22 extends from the main portion 21.

The fixing portion 22 can be substantially perpendicular to the main portion 21. The fixing portion 22 defines a fixing hole 220. Each fixing piece 24 extends from the main portion 21. Each fixing piece 24 defines a fastening hole 240. The two locking pieces 26 are located on one side of the main portion 21 away from the fixing portion 22.

Each slider 30 includes a stopper portion 32, a sliding plate 34, and a plurality of screws 36. The stopper portion 32 includes two assembly portions 320 and a protrusion 322. The protrusion 322 is located between the two assembly portions 320. The two assembly portions 320 can be elastically deformable. The sliding plate 34 includes a body 340 and an operation piece 342. The operation piece 342 extends from the body 340. The operation piece 342 can be substantially perpendicular to the body 340. The body 340 defines four sliding grooves 3402 and two recesses 3406. The body 340 includes a positioning post 3404.

Each sliding bar 40 includes a plurality of hooks 42. The bracket 50 includes a cover 52 and a baffle 54. The cover 52 includes a top plate 520 and two mounting plates 522. The two mounting plates 522 extend from the two sides of the top plate 520 and are substantially perpendicular to the top plate 520. The two mounting plates 522 are substantially parallel to the each other. The baffle 54 is substantially perpendicular to the top plate 520 and two mounting plates 522. Each mounting plate 522 defines a groove 5222 and a plurality of locking grooves 5228. The groove 5222 is defined in one sides of the mounting plate 522 away from the baffle 54. The groove 5222 defines a slot 5224 and a positioning groove 5226. The slot 5224 communicates with the positioning groove 5226. The slot 5224 extends from the positioning groove 5226 to an edge of the mounting plate 522. An extending direction of the slot 5224 is substantially perpendicular to an extending direction of the positioning groove 5226.

FIG. 3 illustrates a view of the assembled chassis 100. In assembly, a motherboard is fixed to the bottom plate 16. The fixing portion 22 of the sliding rail 20 is fixed to the front plate 14 through the fixing hole 220. Two locking pieces 26 are engaged with the locking portions 120 of the side plate 12. The two sliding rails 20 are respectively fixed to the two side plates 12. The two sliding rails 20 are substantially parallel to each other. The two assembly portions 320 of each stopper portion 32 lock with the two sides of the sliding rail 20. The two stopper portions 32 are respectively fixed to the two sliding rails 20. Each screw 36 extends from one of the four sliding grooves 3402 into the fastening hole 240 to fix the sliding plate 34 to the sliding rail 20. The operation piece 342 is substantially parallel to the bottom plate 16. The protrusion 322 is received in the one of the two recesses 3406. A storage device (not shown) can be fixed to the top plate 520 of the bracket 50. The plurality of hooks 42 are engaged with the plurality of locking grooves 5228 to fix the two sliding bars 40 to the bracket 50. The two sliding bars 40 are substantially parallel to each other. The two sliding bars 40 are respectively received in the two sliding rails 20 and move along the two sliding bars 40. The bracket 50 moves relative to the shell 10 until the positioning post 3404 is received in the slot 5224. The operation piece 342 is provided a force and the sliding plate 34 moves along the sliding groove 3402. The protrusion 322 is received in another recess 3406. The positioning post 3404 moves from the slot 5224 to an end of the positioning groove 5226. The positioning post 3404 is engaged with the positioning groove 5226 and is located at a first position. The bracket 50 is fixed to the shell 10. The storage device is located above the motherboard.

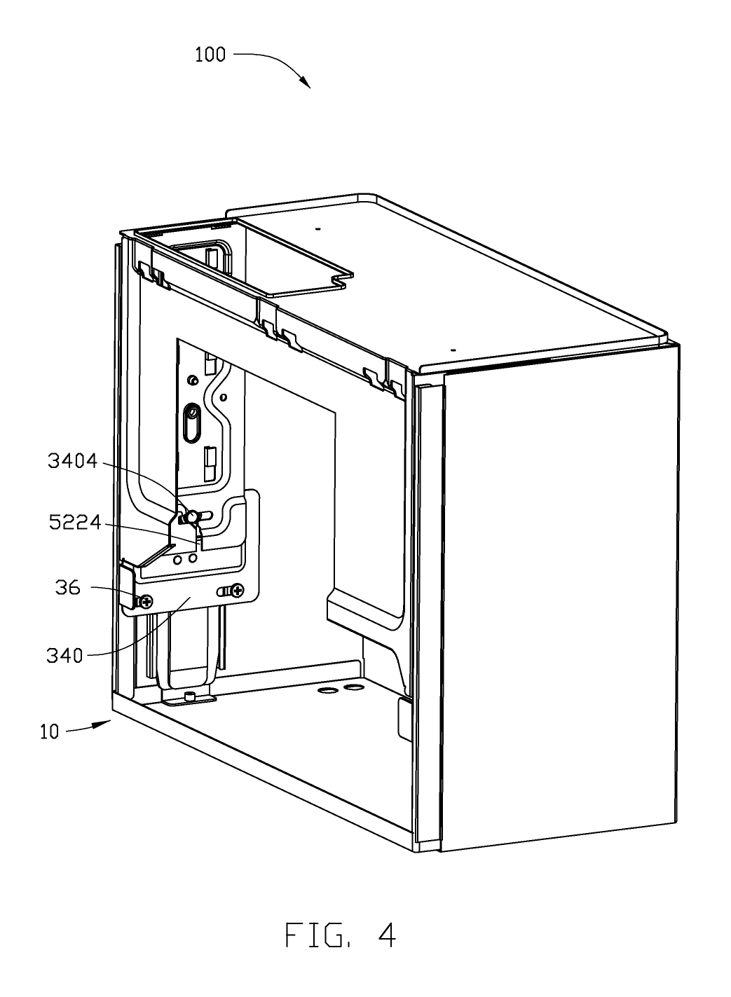

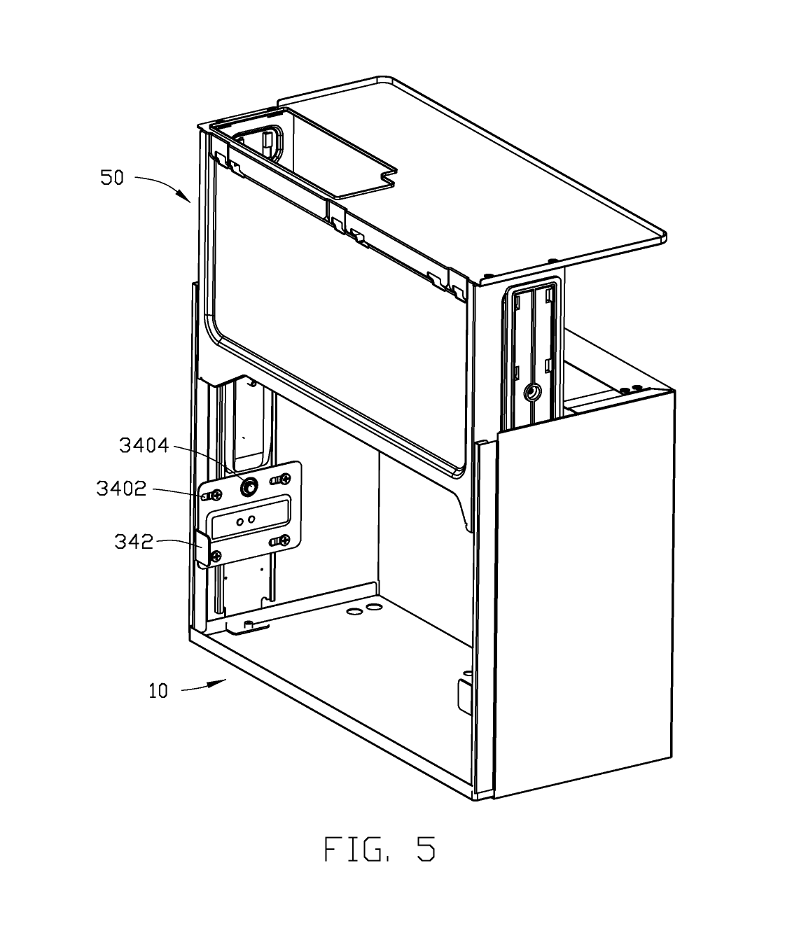

FIGS. 4 and 5 illustrate view of the chassis 100 is disassembled. When the motherboard needs to be removed from the shell 10, the operation piece 342 provides a force and the protrusion 322 moves from one recess 3406 to an opposite side. The positioning post 3404 moves from the first position to a second position along the positioning groove 5226. The positioning post 3404 moves along a first direction which is substantially perpendicular to the bottom plate 16. When the positioning post 3404 at the second position, the bracket 50 is unlocked with the shell 10. The bracket 50 is forced to move. The positioning post 3404 moves from positioning groove 5226 to the slot 5224 and moves along the slot 5224. The bracket 50 moves along a second direction. The second direction is substantially parallel to the bottom plate 16 and is substantially perpendicular to the first direction.

The embodiments shown and described above are only examples. Many details are often found in the art such as the other features of a chassis. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A chassis comprising:
a shell;
two sliding rails secured to the shell;
a slider slidably secured to one of the two sliding rails, and the slider comprising a positioning post; and
a bracket defining a groove;
wherein the positioning post is configured to move from a first position to a second position along the groove; when the positioning post is located at the first position, the bracket is engaged with the shell; and when the positioning post is located at the second position, the bracket is unlocked with the shell and is configured to move away from the shell.

2. The chassis of claim 1, wherein when the positioning post moving from the first position to the second position, the positioning post moves along a first direction, the bracket moves along a second direction relative to the shell, and the first direction is substantially perpendicular to the second direction.

3. The chassis of claim 2, wherein the shell comprises a bottom plate, and the second direction is parallel to the bottom plate.

4. The chassis of claim 1, wherein the groove defines a slot and a positioning groove, the slot communicates with the positioning groove, and an extending direction of the slot is substantially perpendicular to an extending direction of the positioning groove.

5. The chassis of claim 4, wherein the bracket comprises cover, the cover comprises a mounting plate, and the slot extends from the positioning groove to an edge of the mounting plate.

6. The chassis of claim 1, wherein the slider comprises a stopper portion and a sliding plate, the stopper portion is fixed to one of the two sliding rails, the stopper portion comprises a protrusion, the sliding plate defines two recesses, the protrusion is received in one of the two recesses, and when the positioning post moving, the protrusion moves from the one recess to the other recess.

7. The chassis of claim 6, wherein the slider comprises at least one screw, the one of the two sliding rail comprises at least one fixing piece, the fixing piece defines a fastening hole, the sliding plate defines at least one sliding groove, and the screw extends from the sliding groove into the fastening hole to fix the sliding plate to the sliding rail.

8. The chassis of claim 6, wherein the sliding plate comprises an operation piece, the shell comprises a bottom plate, and the operation piece is substantially parallel to the bottom plate.

9. The chassis of claim 1, further comprising two sliding bars, each sliding bar comprising a plurality of hooks, wherein the bracket defines a plurality of locking grooves, and the plurality of hooks are engaged with the plurality of locking groove to fix the two sliding bars to the bracket.

10. The chassis of claim 9, wherein the two sliding bars are substantially parallel to the each other.

11. A chassis comprising:
a shell;
two sliding rails secured to the shell;
a slider comprising a positioning post, and the positioning post is configured to slide along a first direction relative to the shell; and
a bracket defining a groove, and the bracket is configured to slide along a second direction relative to the shell;
wherein when the positioning post is located at the one end of the groove, the bracket is locked with the shell, when the positioning post sliding along the first direction and the bracket sliding along the second direction, the bracket is unlocked with the shell and is configured to move away from the shell.

12. The chassis of claim 11, wherein the first direction is substantially perpendicular to the second direction.

13. The chassis of claim 12, wherein the shell comprises a bottom plate, and the second direction is parallel to the bottom plate.

14. The chassis of claim 11, wherein the groove defines a slot and a positioning groove, the slot communicates with the positioning groove, and an extending direction of the slot is substantially perpendicular to an extending direction of the positioning groove.

15. The chassis of claim 14, wherein the bracket comprises cover, the cover comprises a mounting plate, and the slot extends from the positioning groove to an edge of the mounting plate.

16. The chassis of claim 15, wherein the slider comprises a stopper portion and a sliding plate, the stopper portion is fixed to one of the two sliding rails, the stopper portion comprises a protrusion, the sliding plate defines two recesses, the protrusion is received in the one of the two recesses, and when the positioning post moving, the protrusion moves from one recess to another.

17. The chassis of claim 16, wherein the slider comprises at least one screw, the one of the two sliding rail comprises at least one fixing piece, the fixing piece defines a fastening hole, the sliding plate defines at least one sliding groove, and the screw extends from the sliding groove into the fastening hole to fix the sliding plate to the sliding rail.

18. The chassis of claim 16, wherein the sliding plate comprises an operation piece, the shell comprises a bottom plate, and the operation piece is substantially parallel to the bottom plate.

19. The chassis of claim 11, further comprising two sliding bars, each sliding bar comprising a plurality of hooks, wherein the bracket defines a plurality of locking grooves, and the plurality of hooks are engaged with the plurality of locking groove to fix the two sliding bars to the bracket.

20. The chassis of claim 19, wherein the two sliding bars are substantially parallel to the each other.
